(19) United States
(12) Patent Application Publication
(10) Pub. No.: US 2026/0185867 A1
(43) Pub. Date: Jul. 2, 2026

(54) SUBSTRATE PROCESSING APPARATUS

(71) Applicant: SEMES CO., LTD., Cheonan-si (KR)

(72) Inventors: Jin Se PARK, Cheonan-si (KR); Seung Hoon OH, Cheonan-si (KR); Eun Seok KIM, Asan-si (KR); Hye Bin GWON, Cheonan-si (KR); Dong Hoon LEE, Seongnam-si (KR); Jung Heum NAM, Gyeongju-si (KR)

(73) Assignee: SEMES CO., LTD., Cheonan-si (KR)

(21) Appl. No.: 19/434,162

(22) Filed: Dec. 29, 2025

(30) Foreign Application Priority Data
Dec. 31, 2024 (KR) 10-2024-0202311

(51) Int. Cl. G01G 23/00; B08B 3/04; F26B 5/00; G01G 21/14; H10P 72/00

(52) U.S. Cl. CPC G01G 23/002; B08B 3/04; F26B 5/005; G01G 21/14; H10P 72/0408; H10P 72/06

(57) ABSTRACT

Provided is an apparatus for processing a substrate, the apparatus including: an index module including a load port and an index robot; and a treating module including a buffer unit, a liquid treating chamber for liquid-treating a substrate, a drying chamber for removing the liquid remaining on the substrate, and a transfer unit for transferring the substrate between the buffer unit, the liquid treating chamber, and the drying chamber, in which the buffer unit includes: a frame; a buffer disposed in an upper space of an inner space of the frame and temporarily storing the substrate transferred between the index module and the treating module; and a weight measuring unit disposed in a lower space of the inner space of the frame and measuring the weight of the substrate.

### CROSS-REFERENCE TO RELATED APPLICATION

This application claims priority to and the benefit of Korean Patent Application No. 10-2024-0202311 filed in the Korean Intellectual Property Office on Dec. 31, 2024, the entire contents of which are incorporated herein by reference.

### TECHNICAL FIELD

The present invention relates to a substrate processing apparatus, and more particularly, to a substrate processing apparatus for liquid-treating a substrate.

### BACKGROUND ART

To manufacture a semiconductor device or liquid crystal display, various processes, such as photolithography, etching, ashing, ion implantation, and thin film deposition, are performed on a substrate. Before or after such a process proceeds, a cleaning process is performed to clean the substrate to remove contaminants and particles generated in each process. In general, the cleaning process includes a process of liquid-treating a substrate and a process of drying a substrate.

After the processing process is completed, the substrate is transferred from a liquid treating chamber to a drying chamber. In this case, when the amount of the organic solvent remaining on the substrate is greater than a preset range, the organic solvent acts as particles and contaminates the peripheral device. In contrast, when the amount of the organic solvent is less than the preset range, a process defect occurs due to a lining phenomenon of the pattern.

In addition, commonly used organic solvents are provided as highly volatile materials, and some of them may volatilize while the substrate is being transferred.

As a result, the weight of the substrate is measured to determine the amount of organic solvent (liquid) remaining on the substrate in the process of setting up the substrate processing facility and the like.

The method of measuring the weight of a substrate in the related art was performed in such a way that an operator directly measures the weight of the substrate. However, this method reduces the working efficiency of the substrate and has a problem that facility may be contaminated.

### SUMMARY OF THE INVENTION

The present invention has been made in an effort to provide a substrate processing apparatus capable of automating a process of measuring weight of a substrate.

The present invention has also been made in an effort to provide a substrate processing apparatus capable of minimizing errors in measuring weight of a substrate.

The objectives of the present disclosure are not limited thereto and other objectives not stated herein may be clearly understood by those skilled in the art from the following description.

An exemplary embodiment of the present disclosure, an apparatus for processing a substrate, the apparatus comprising: an index module including a load port and an index robot; and a treating module including a buffer unit, a liquid treating chamber for liquid-treating a substrate, a drying chamber for removing the liquid remaining on the substrate, and a transfer unit for transferring the substrate between the buffer unit, the liquid treating chamber, and the drying chamber, wherein the buffer unit may include: a frame; a buffer disposed in an upper space of an inner space of the frame and temporarily storing the substrate transferred between the index module and the treating module; and a weight measuring unit disposed in a lower space of the inner space of the frame and measuring the weight of the substrate.

According to the exemplary embodiment of the present invention, wherein the weight measuring unit may include: a support on which the substrate is placed; a weight measuring sensor for measuring the weight of the substrate placed on the support; and a measuring device base for supporting the weight measuring sensor.

According to the exemplary embodiment of the present invention, wherein the weight measuring sensor may include a load cell.

According to the exemplary embodiment of the present invention, wherein the weight measuring sensor has a cantilever shape, and has one end supported by the measuring device base, and the support may be installed on the other end of the weight measuring sensor.

According to the exemplary embodiment of the present invention, wherein the weight measuring unit further may include a level-adjusting member for adjusting horizontality of the support.

According to the exemplary embodiment of the present invention, wherein the support includes: a bottom plate; and a plurality of support protrusions protruding upward from the bottom plate and being in contact with a bottom surface of the substrate, and the plurality of support protrusions may be disposed to support the substrate at points spaced apart from each other.

According to the exemplary embodiment of the present invention, wherein a distance between two support protrusions adjacent to each other among the plurality of support protrusions may be smaller than a radius of the substrate.

According to the exemplary embodiment of the present invention, wherein the transfer unit includes: a base; and a hand configured to advance and retract relative to the base and support the substrate, and the hand and the support protrusions may be disposed so that the substrate is handed over between the hand and the plurality of support protrusions as the hand may be raised and lowered.

According to the exemplary embodiment of the present invention, further comprising: airflow supply unit for providing descending airflow to a region where the buffer unit is provided, wherein the buffer unit further may include a cover for dividing the inner space of the frame into the upper space and the lower space.

According to the exemplary embodiment of the present invention, wherein a vertically penetrating hole may be formed in the cover.

According to the exemplary embodiment of the present invention, wherein the upper space has an open front face facing the index robot and an open rear face facing the transfer unit, and in the lower space, the front face and the rear face are closed, and an opening through which the substrate enters and exits may be formed on the rear face.

According to the exemplary embodiment of the present invention, further may comprising: a shutter configured to open and close the opening.

An exemplary embodiment of the present disclosure, an apparatus for processing a substrate, the apparatus comprising: an index module including a load port and an index robot; and a treating module including a buffer unit, a process chamber for processing a substrate, and a transfer unit for transferring the substrate between the buffer unit and the process chamber, wherein the buffer unit may include: a frame; a buffer disposed in an upper space of an inner space of the frame and temporarily storing the substrate transferred between the index module and the treating module; a weight measuring unit disposed in a lower space of the inner space of the frame and measuring a weight of the substrate; and a cover for dividing the inner space of the frame into the upper space and the lower space.

According to the exemplary embodiment of the present invention, wherein the weight measuring unit includes: a support on which the substrate is placed; a weight measuring sensor for measuring the weight of the substrate placed on the support; and a measuring device base for supporting the weight measuring sensor, the support includes: a bottom plate; and a plurality of support protrusions protruding upward from the bottom plate and being in contact with a bottom surface of the substrate, the plurality of support protrusions is disposed to support the substrate at points spaced apart from each other, and a distance between two support protrusions adjacent to each other among the plurality of support protrusions may be smaller than a radius of the substrate.

According to the exemplary embodiment of the present invention, wherein a vertically penetrating hole may be formed in the cover.

According to the exemplary embodiment of the present invention, wherein the weight measuring sensor has a cantilever shape, and has one end supported by the measuring device base, and the support may be installed on the other end of the weight measuring sensor.

According to the exemplary embodiment of the present invention, wherein the upper space has an open front face facing the index robot and an open rear face facing the transfer unit, and in the lower space, the front face and the rear face are closed, and an opening through which the substrate enters and exits may be formed on the rear face.

An exemplary embodiment of the present disclosure, an apparatus for processing a substrate, the apparatus comprising: an index module including a load port and an index robot; and a treating module including a transfer frame in which a buffer unit, a liquid treating chamber for liquid-treating a substrate, a drying chamber for removing the liquid remaining on the substrate by supplying a supercritical fluid to the substrate, and a transfer unit for transferring the substrate between the buffer unit, the liquid treating chamber, and the drying chamber, wherein the buffer unit includes: a frame; a buffer disposed in an upper space of an inner space of the frame and temporarily storing the substrate transferred between the index module and the treating module; a weight measuring unit disposed in a lower space of the inner space of the frame and measuring a weight of the substrate; and a cover for dividing the inner space of the frame into the upper space and the lower space, the upper space has an open front face facing the index robot and an open rear face facing the transfer unit, in the lower space, the front face and the rear face are all closed, and an opening through which the substrate enters and exits is formed on the rear face, a vertically penetrating hole may be formed in the cover, and the weight measuring unit may include: a support on which the substrate is placed; a weight measuring sensor for measuring the weight of the substrate placed on the support; and a measuring device base for supporting the weight measuring sensor.

According to the exemplary embodiment of the present invention, wherein the weight measuring unit further includes a level-adjusting member for adjusting horizontality of the support, the support includes: a bottom plate; and a plurality of support protrusions protruding upward from the bottom plate and being in contact with a bottom surface of the substrate, the plurality of support protrusions is disposed to support the substrate at points spaced apart from each other, and a distance between two support protrusions adjacent to each other among the plurality of support protrusions may be smaller than a radius of the substrate.

According to the exemplary embodiment of the present invention, wherein the weight measuring sensor has a cantilever shape, and has one end supported by the measuring device base, and the support may be installed on the other end of the weight measuring sensor.

According to the exemplary embodiment of the present invention, it is possible to automate a process of measuring weight of a substrate.

Further, according to the exemplary embodiment of the present invention, it is possible to minimize errors in measuring weight of a substrate.

Effects of the present disclosure are not limited to those described above and effects not stated above will be clearly understood to those skilled in the art from the specification and the accompanying drawings.

### BRIEF DESCRIPTION OF THE DRAWINGS

The various features and advantages of the non-limiting exemplary embodiment of the present specification may become more apparent by reviewing the detailed description together with the accompanying drawings. The accompanying drawings are provided for illustrative purposes only and should not be construed as limiting the scope of claims. The accompanying drawings are not considered to be drawn to scale unless explicitly stated. For clarity, the various dimensions of the drawings may have been exaggerated.

FIG. 1 is a diagram schematically illustrating a substrate processing apparatus according to an exemplary embodiment of the present invention.

FIG. 2 is a perspective view illustrating a buffer unit of FIG. 1.

FIG. 3 is a diagram schematically illustrating an inside of the buffer unit of FIG. 2.

FIG. 4 is a diagram schematically illustrating airflow introduced into the buffer unit.

FIG. 5 is a diagram illustrating a weight measuring unit of FIG. 3 in detail.

FIG. 6 is a perspective view illustrating a transfer unit according to an exemplary embodiment of the present invention.

FIG. 7 is a diagram illustrating a state in which a substrate supported by a hand of FIG. 6 is transferred to the weight measuring unit to measure the weight.

FIG. 8 is a top plan view of a weight measurement space of FIG. 7.

FIG. 9 is a diagram schematically illustrating an exemplary embodiment of a first process chamber of FIG. 1.

FIG. 10 is a diagram schematically illustrating an exemplary embodiment of a second process chamber of FIG. 1.

FIG. 11 is a flowchart illustrating a method of processing a substrate using the above-described substrate processing apparatus.

FIG. 12 is a diagram illustrating a shape of the buffer unit in a substrate loading operation of FIG. 11.

FIGS. 13 to 16 are diagrams illustrating the buffer unit and the hand in a first weight measuring operation of FIG. 10.

FIG. 17 is a diagram illustrating a state in which the weight of the substrate W is measured in a second weight measuring operation.

FIG. 18 is a diagram illustrating a state of the buffer unit and the hand when a substrate unloading operation of FIG. 10 is performed.

### DETAILED DESCRIPTION

Example embodiments will now be described more fully with reference to the accompanying drawings. Example embodiments are provided so that this disclosure will be thorough and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

When the term “same” or “identical” is used in the description of example embodiments, it should be understood that some imprecisions may exist. Thus, when one element or value is referred to as being the same as another element or value, it should be understood that the element or value is the same as the other element or value within a manufacturing or operational tolerance range (e.g., ±10%).

When the terms “about” or “substantially” are used in connection with a numerical value, it should be understood that the associated numerical value includes a manufacturing or operational tolerance (e.g., ±10%) around the stated numerical value. Moreover, when the words “generally” and “substantially” are used in connection with a geometric shape, it should be understood that the precision of the geometric shape is not required but that latitude for the shape is within the scope of the disclosure.

Unless otherwise defined, all terms (including technical and scientific terms) used herein have the same meaning as commonly understood by one of ordinary skill in the art to which example embodiments belong. It will be further understood that terms, including those defined in commonly used dictionaries, should be interpreted as having a meaning that is consistent with their meaning in the context of the relevant art and will not be interpreted in an idealized or overly formal sense unless expressly so defined herein.

In the present exemplary embodiment, the present invention will be described based on the process in which a substrate W is liquid-treated by supplying a liquid, such as a cleaning liquid, onto the substrate W as an example. However, the present exemplary embodiment is not limited to the cleaning process, and may be applied to various processes of processing the substrate W using a liquid, such as an etching process, an ashing process, or a developing process.

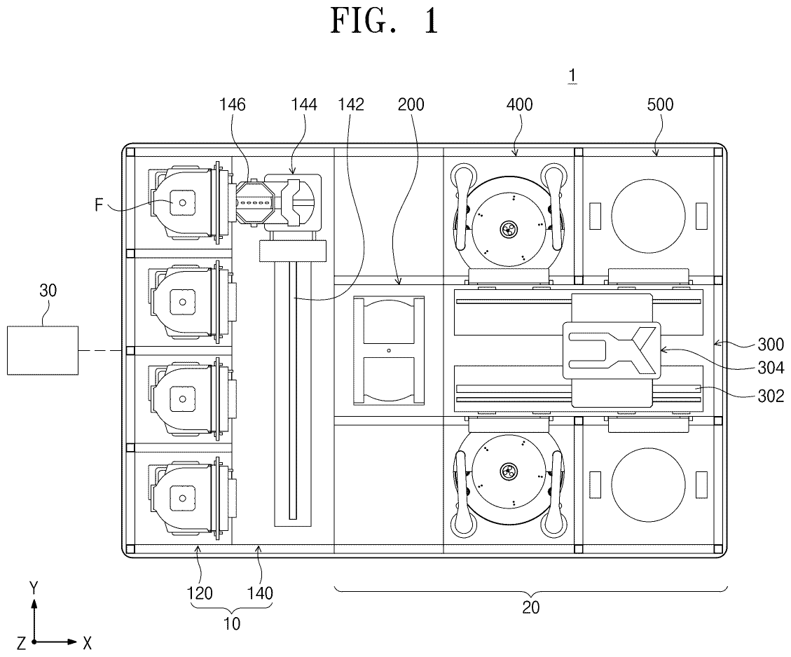

Hereinafter, an exemplary embodiment of the present invention will be described in detail with reference to FIGS. 1 to 18. A substrate processing apparatus 1 according to an exemplary embodiment of the present invention may perform a cleaning process including a drying process of drying a substrate W using a process fluid.

FIG. 1 is a plan view schematically illustrating a substrate processing apparatus according to an exemplary embodiment of the present invention. Referring to FIG. 1, a substrate processing apparatus 1 includes an index module 10, a treating module 20, and a controller 30. According to an exemplary embodiment, the index module 10 and the treating module 20 are disposed along one direction. Hereinafter, a direction in which the index module 10 and the treating module 20 are arranged is defined as a first direction X. When viewed from above, a direction perpendicular to the first direction X is defined as a second direction Y, and a direction perpendicular to the plane including both the first direction X and the second direction Y is defined as a third direction Z.

The index unit 10 transfers the substrate W from a container F in which the substrate W is accommodated to the treating unit 20 for processing the substrate W. The index module 10 accommodates the substrate W completely processed in the treating module 20 into the container F. A longitudinal direction of the index module 10 is provided in the second direction Y. The index module 10 includes a load port 120 and an index frame 140.

The container F in which the substrate W is accommodated is seated on the load port 120. Based on the index frame 140, the load port 120 is located at a side opposite to the treating module 20. A plurality of load ports 120 may be provided. The plurality of load ports 120 may be arranged in a line along the second direction Y. The number of load ports 120 may increase or decrease according to the process efficiency and footprint conditions of the treating module 20.

A plurality of slots (not illustrated) is formed in the container F. The slots (not illustrated) may accommodate the substrates W in a state in which the substrates W are disposed horizontally with respect to the ground. As the container F, an airtight container, such as a Front Open Unified Pod (FOUP), may be used. The container F may be placed on the load port 120 by a transfer means (not illustrated), such as an overhead transfer, an overhead conveyor, or an automatic guided vehicle, or an operator.

An index rail 142 and an index robot 144 are provided inside the index frame 140. The index rail 142 is provided in the index frame 140 along the second direction Y in its longitudinal direction. The index robot 144 may transfer the substrate W. The index robot 144 may transfer the substrate W between the index module 10 and a buffer unit 200 to be described later.

The index robot 144 includes an index hand 146. The substrate W is seated on the index hand 146. The index hand 146 may be provided on the index rail 142 to be movable along the second direction Y. Accordingly, the index hand 146 may be moved forward and backward along the index rail 142. Also, the index hand 146 may be provided to be rotatable with respect to the third direction Z. Also, the index hand 146 may be provided to be vertically movable along the third direction Z. A plurality of index hands 146 may be provided. A plurality of index hands 146 may be provided to be spaced apart from each other in the vertical direction. A plurality of index hands 146 may move forward, backward, and rotate independently of each other.

The controller 30 controls the substrate processing apparatus 1. The controller 30 may include a process controller formed of a microprocessor (computer) that executes the control of the substrate processing apparatus 1, a user interface formed of a keyboard in which an operator performs a command input operation or the like in order to manage the substrate processing apparatus 1, a display for visualizing and displaying an operation situation of the substrate processing apparatus 1, and the like, and a storage unit storing a control program for executing the process executed in the substrate processing apparatus 1 under the control of the process controller or a program, that is, a treating recipe, for executing the process in each component according to various data and treating conditions. Further, the user interface and the storage unit may be connected to a process controller. The processing recipe may be stored in a storage medium in the storage unit, and the storage medium may be a hard disk, and may also be a portable disk, such as a CD-ROM or a DVD, or a semiconductor memory, such as a flash memory.

The controller 30 may control the substrate processing apparatus 1 to perform the substrate processing method described below. For example, the controller 30 may control components provided to a weight measuring unit 250, a transfer unit 304, and process chambers 400 and 500 to perform a substrate processing method to be described later.

The treating module 20 includes a buffer unit 200, a transfer frame 300, and a process chamber 400. The buffer unit 200 provides a space in which the substrate W loaded into the treating module 20 and the substrate W unloaded from the treating module 20 stay temporarily. The transfer frame 300 provides a transfer space for transferring the substrate W between the buffer unit 200 and the process chambers 400 and 500.

The buffer unit 200 may be disposed between the index frame 140 and the transfer frame 300. The buffer unit 200 may be located at one end of the transfer frame 300.

The buffer unit 200 provides a space in which the substrate W stays before the substrate W is transferred between the index robot 144 and the transfer unit 304. The buffer unit 200 will be described later.

A slot (not illustrated) in which the substrate W is placed is provided in the buffer unit 200. A plurality of slots (not illustrated) is provided. A plurality of slots (not illustrated) is provided to be spaced apart from each other along the third direction Z. The front face is a face facing the index module 10, and the rear face is a face facing the transfer frame 300. The index robot 144 may approach the buffer unit 200 through the front face, and the transfer robot 300 to be described below may approach the buffer unit 200 through the rear face.

The transfer frame 300 may be provided so that a longitudinal direction is the first direction X. The process chambers 400 and 500 may be disposed on opposite sides of the transfer frame 300. The process chambers 400 and 500 may be disposed on a side portion of the transfer frame 300. The transfer frame 300 and the process chambers 400 and 500 may be disposed along the second direction Y.

According to the example, the process chambers 400 and 500 are disposed on opposite sides of the transfer frame 300. At one side of the transfer frame 300, the process chambers 400 and 500 may be provided in an array of A×B (each of A and B is 1 or a natural number larger than 1) in the first direction X and the third direction Z. Herein, A is the number of process chambers 400 and 500 provided in a row along the first direction X, and B is the number of process chambers 400 and 500 provided in a row along the third direction Z. For example, when four process chambers 400 and 500 are provided at one side of the transfer frame 300, the process chambers 400 may be arranged in a 2×2 array. The number of process chambers 400 and 500 may increase or decrease. Unlike the above description, the process chambers 400 and 500 may be provided as a single layer on one side and opposite sides of the transfer frame 300.

The transfer frame 300 includes a guide rail 242 and a transfer unit 304. The guide rail 242 is provided within the transfer frame 300 in the first direction X in a longitudinal direction thereof. The transfer unit 304 may be provided on the guide rail 242 to be able to move linearly along the first direction X. Also, the transfer unit 304 may be provided to be rotatable with respect to the third direction Z. Also, the transfer unit 304 may be provided to be vertically movable along the third direction Z. The transfer robot 304 transfers the substrate W between the buffer unit 200 and the process chambers 400 and 500.

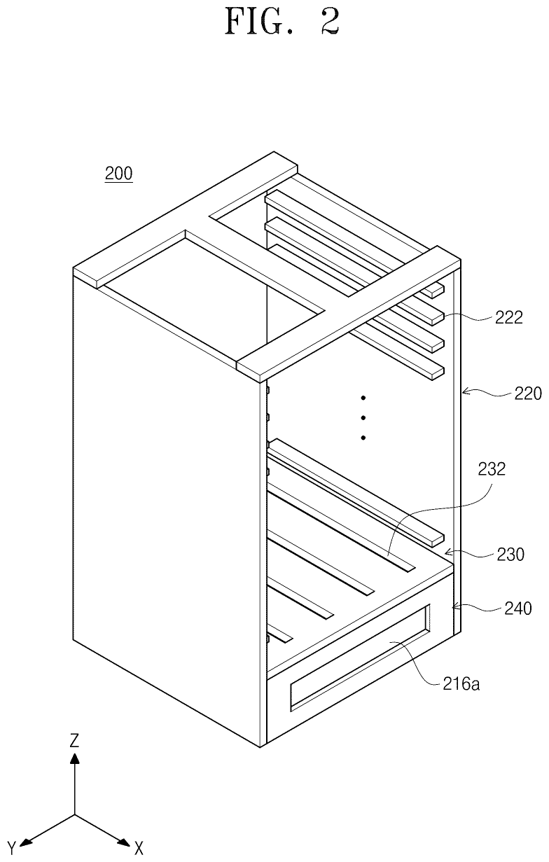

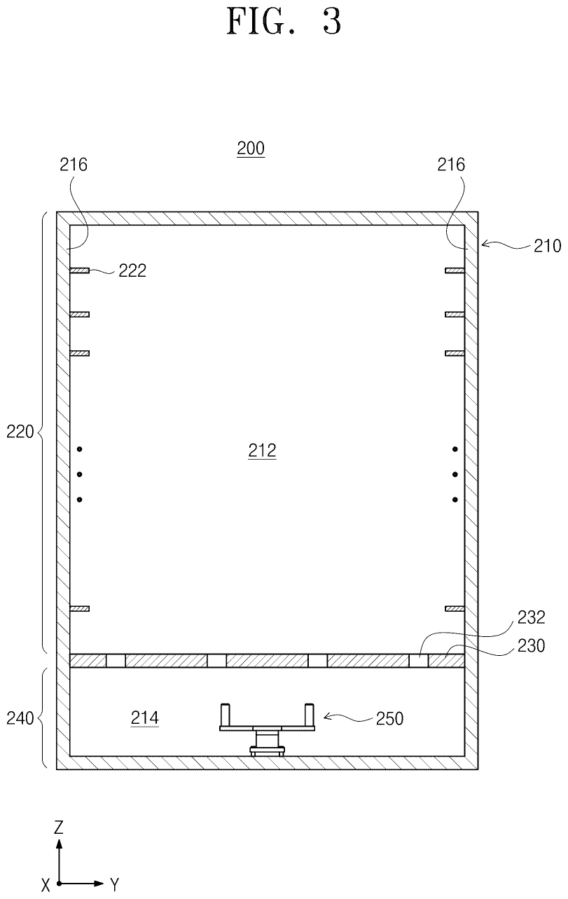

FIG. 2 is a perspective view illustrating a buffer unit of FIG. 1, and FIG. 3 is a diagram schematically illustrating an inside of the buffer unit of FIG. 2.

Hereinafter, the buffer unit according to the exemplary embodiment of the present invention will be described in detail with reference to FIGS. 2 to 3.

The buffer unit 200 includes a frame 210, a buffer part 220, a cover 230, and a weight measuring part 240.

The frame 210 has a rectangular parallelepiped shape. The inside of the frame 210 is divided into an upper space and a lower space by a cover 230 to be described later. The upper space is an inner space of the buffer part 220 and is provided as a buffer space 212 in which the substrate W is stored. The lower space is an inner space of the weight measuring part 240 and is provided as a weight measurement space 214 capable of measuring the weight of the substrate W.

The buffer part 220 functions as a buffer in which the substrate W is temporarily stored. The buffer part 220 has a buffer space 212 in which the substrate W is temporarily stored. The buffer part 220 has a rectangular parallelepiped shape in which opposite sides facing each other are opened. A front face and a rear face of the buffer part 220 are opened. The front face and the rear face may be faces formed side by side along the first direction X. In other words, the buffer space 212 opens the front face facing the index robot 144 and the rear face facing the transfer frame 300 in which the transfer unit 304 is provided. The open front face of the buffer part 220 is provided as a surface facing the transfer frame 140, and the open rear face of the buffer part 220 is provided as a face facing the transfer unit 304. The substrate W may be loaded or unloaded through the open faces of the buffer part 220.

The buffer part 220 includes a slot member 222. The slot member 222 supports a substrate in the buffer space 224. A plurality of slot members 222 is provided and is arranged to be spaced apart from each other in the vertical direction. The slot member 222 is provided as a plurality of support slots for receiving the substrate W in a state in which the substrate W is disposed horizontally with respect to the ground. For example, the slot member 222 may include two support slots facing each other. The support slots facing each other are positioned on opposite inner surfaces of the buffer part 220. The slot members (hereinafter, referred to as upper slot members) positioned in an upper region of the buffer space 212 are positioned to be spaced apart from each other at the same interval of a first interval. The slot members (hereinafter, referred to as lower slot members) positioned in the lower region of the buffer space 212 are positioned to be spaced apart from each other at the same interval of the first interval. The lowermost support slot of the upper slot members and the uppermost support slot of the lower slot members are spaced apart from each other at a second interval larger than the first interval. According to an example, one of the upper slot member and the lower slot member may be a slot member 222 for loading the substrate W into the buffer space 212 from the transfer unit 304, and the other may be a slot member 222 for unloading the substrate W stored in the buffer space 212 by the transfer unit 304.

The weight measuring part 240 has a weight measurement space 214 therein. The weight measuring unit 250, which will be described later, is disposed in the weight measurement space 214.

The weight measuring part 240 has a rectangular parallelepiped shape in which all four side surfaces 216 are closed. In other words, unlike the buffer space 212, the weight measurement space 214 has a front face facing the index robot 144 and a rear face facing the transfer frame 300 that are closed.

An opening 216a is formed in the rear surface of the weight measurement space 214. A hand 320 of the transfer unit 304, which will be described below, may enter and exit through the opening 216a. The substrate W supported by the hand 320 may be loaded into the weight measurement space 214 through the opening 216a, and a weight of the substrate W may be measured through the weight measuring unit 250 provided in the weight measurement space 214. A shutter (not illustrated) may be provided in the opening 216a. The opening 216a may be opened and closed by a shutter (not illustrated).

The cover 230 divides an inner space of the frame 210 into a buffer space 212 and the weight measurement space 214. The cover 230 may be a partition wall that divides the buffer unit 200 into the buffer part 220 and the weight measuring part 240. The cover 230 is installed above the weight measurement space 214. The cover 230 covers an upper portion of the weight measurement space 214.

A hole 232 penetrating the cover 230 in the vertical direction is formed in the cover 230. The hole 232 may be provided as an elongated hole extending in the first direction X. The hole 232 may be provided as a slit. A plurality of holes 232 may be provided, and may be spaced apart from each other by a predetermined distance in the second direction Y. As the hole 232 is formed in the cover 230, the atmosphere in the weight measurement space 214 may be discharged to the outside.

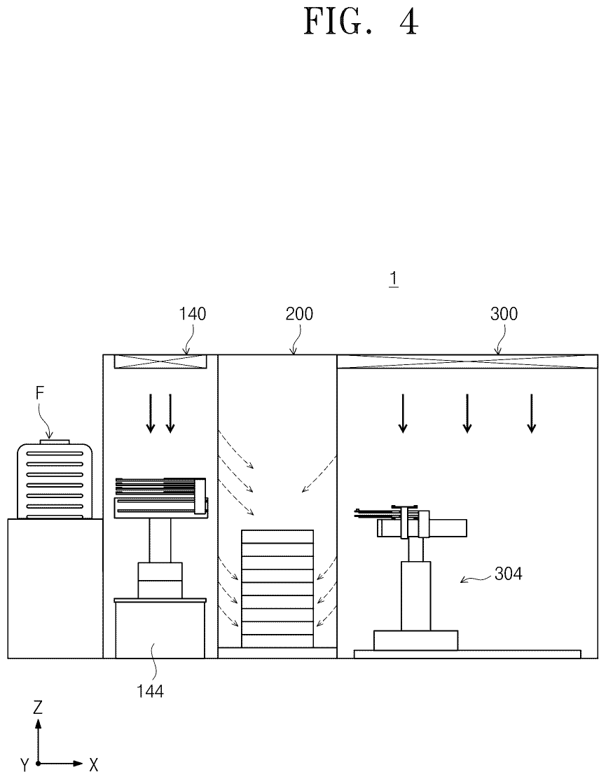

FIG. 4 is a diagram schematically illustrating airflow introduced into the buffer unit. Referring to FIG. 4, an airflow supply unit may be provided above the index frame 140 and the transfer frame 300. The airflow supply unit supplies airflow to the inner spaces of the index frame 140 and the transfer frame 300. The airflow supply unit may supply descending airflow to the inner space. The descending airflow supplied by the airflow supply unit may be provided as a region in which the buffer unit 200 is provided. As illustrated in FIG. 4, some descending airflow may be introduced into the buffer unit 200. In this case, when the weight measuring unit 250 measures the weight of the substrate W in the weight measurement space 214, the descending airflow introduced to the substrate W may collide with the substrate W and cause an error in weight measurement of the substrate W. The cover 230 divides the frame 210 into the weight measurement space 214 and the buffer space 212 and prevents the descending airflow from being introduced into the weight measurement space 214, thereby minimizing a measurement error when the weight measuring unit 250 measures the weight of the substrate W.

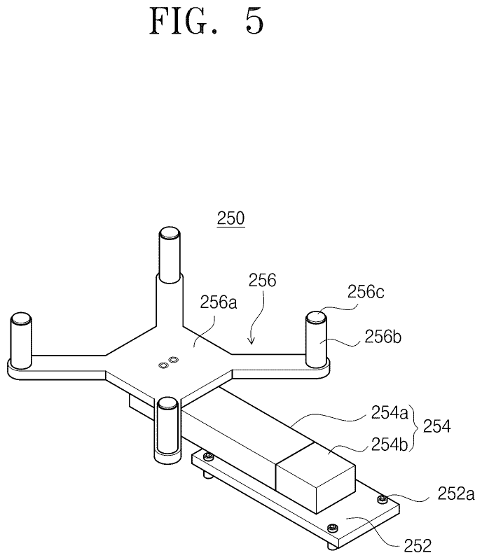

FIG. 5 is a diagram illustrating the weight measuring unit of FIG. 3 in detail. Hereinafter, the weight measuring unit 250 of the present invention will be described in detail with reference to FIG. 5.

The weight measuring unit 250 measures a weight of the substrate W. The weight measuring unit 250 includes a measuring device base 252, a weight measuring sensor 254, and a support 256.

The measuring device base 252 is installed on a bottom surface of the weight measurement space 214. The measuring device base 252 may be provided as a flat plate. The measuring device base 252 may be installed in the weight measurement space 214 to be fixed in the first direction X and the second direction Y. The measuring device base 252 may further include a level-adjusting member 252a.

The level-adjusting member 252a adjusts the horizontality of the measuring device base 252, and may adjust the degree of horizontality of the substrate W placed on the support 256 by adjusting the horizontality of the support 256. The level-adjusting member 252a may be installed at a corner of the measuring device base 252. The level-adjusting member 252a may be provided as, for example, a headless bolt, to adjust the height of each corner of the measuring device base 252 in the third direction Z.

The weight measuring sensor 254 measures the weight of the substrate W loaded into the weight measurement space 214. The weight measuring sensor 254 is fixedly installed on the measuring device base 252. The weight measuring sensor 254 may include, for example, a load cell 254a for measuring strain through a strain gauge, and an indicator 254b for transmitting the value measured by the load cell 254a to the controller 30. The weight measuring sensor 254 transmits the measured weight information to the controller 30. The weight measuring sensor 254 may be provided on the measuring device base 252 in a cantilever shape. One end of the weight measuring sensor 254 may be fixedly installed on the measuring device base 252, and the other end of the weight measuring sensor 254 may be configured as a free end, and the support 256 may be installed thereon. When the substrate W is seated on the support 256, the support 256 and the other end of the weight measuring sensor 254 are deformed according to the weight of the substrate W, and the weight of the substrate W may be measured using the strain at which the weight measuring sensor 254 is deformed.

The support 256 may support the substrate W. The support 256 includes a bottom plate 256a and a support protrusion 256b. The bottom plate 256a is installed on the weight measuring sensor 254. The bottom plate 256a may be installed on the end of the weight measuring sensor 254. The end of the weight measuring sensor 254 in which the bottom plate 256a is installed may be provided as a free end.

The support protrusion 256b protrudes upwardly from the bottom plate 256a to be in contact with the bottom surface of the substrate W placed on the support 256. The support protrusion 256b is provided flat to support the bottom surface of the substrate W. A guide 256c made of a material having a high coefficient of friction so as to support the substrate W and prevent the substrate W from slipping may be further provided on an upper end of the support protrusion 256b.

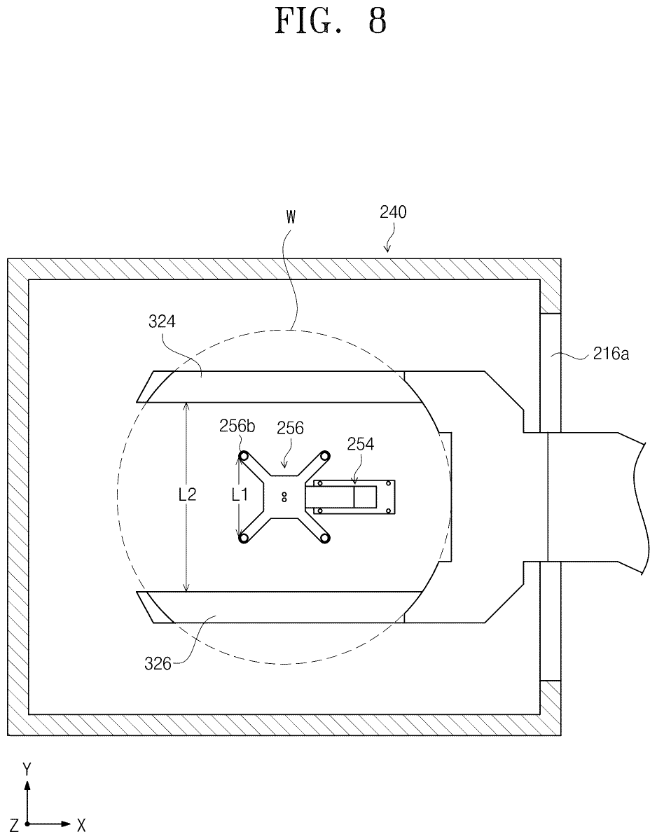

A plurality of support protrusions 256b is provided. A plurality of support protrusions 256b may be disposed to support the bottom surface of the substrate W at points spaced apart from each other. A plurality of support protrusions 256b may be disposed at positions at which warpage due to the weight of the substrate W may be minimized when supporting the bottom surface of the substrate W. For example, four support protrusions 256b may be provided and arranged to support the substrate W by four points. The support protrusion 256b may be arranged to surround the virtual center when viewed from above. In FIG. 8, the weight measuring unit viewed from above is illustrated. Referring further to FIG. 8, a distance L1 between two adjacent support protrusions 256b among the plurality of support protrusions 256b may be provided to be smaller than a radius of the substrate W.

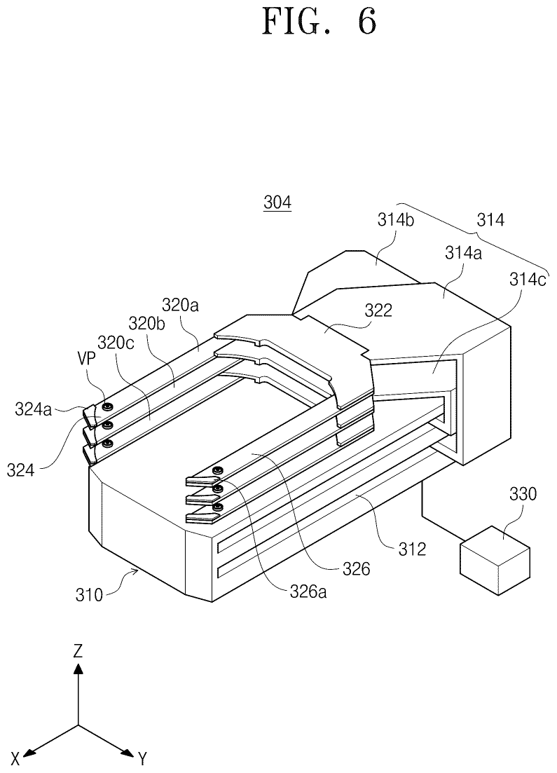

FIG. 6 is a perspective view illustrating the transfer unit according to the exemplary embodiment of the present invention. Referring to FIG. 6, the transfer unit 304 includes a base 310, an arm 314, a hand 320, and a driving unit 330.

The base 310 is installed to be movable along the guide rail 302. The base 310 supports the arm 314 and the hand 320 connected to the arm 314. The arm 314 is connected with the base 310. An end of the arm 314 is coupled to the hand 320.

The base 310 may be axially rotated with respect to a support shaft (not illustrated) in the third direction Z. The base 310 may have a generally rectangular parallelepiped shape. The base 310 is provided such that a longitudinal direction thereof is directed in a horizontal direction. A guide 312 is provided on the base 310. The guide 312 guides the movement direction of the arm 314 so that the arm 314 and the hand 320 coupled to the arm 314 may move linearly along the longitudinal direction of the base 310, that is, the second direction Y of FIG. 6. A plurality of guides 312 may be provided. The arm 314 is provided to be able to advance and retract relative to the base 310 by the driving unit 330. When the arm 314 advances relative to the base 310, the hand 320 may be placed in a forward position, and when the arm 314 retracts relative to the base 310, the hand 320 may be placed in a retracted position. When the hand 320 is placed in the retracted position, the hand 320 may be located above the base 310.

According to an example, the same number of guides 312 as the number of arms 314 may be provided. Each of the guides 312 may be provided such that a longitudinal direction thereof is parallel to the base 310.

The arm 314 and the hand 320 coupled to the arm 314 may be stacked on the base 310 to be spaced apart from each other in a vertical direction, that is, the third direction Z, and may be provided in plural. A plurality of arms 314 may be linearly driven independently of each other by the driving unit 330. Accordingly, the plurality of transfer hands 320 is capable of moving forward and backward, and rotating independently of each other by the driving unit 330.

In the following exemplary embodiment, the present invention will be described based on the illustration that the transfer unit 300 includes three arms 314a, 314b, and 314c in which one hand 320 is coupled, that is, the transfer unit 300 includes a first hand 320a, a second hand 320b, and a third hand 320c, but unlike this, the number of arms 314 and the hands 320 may be freely changed according to the process efficiency of the substrate processing apparatus 1.

The substrate W is placed on the hand 320. The hand 320 directly loads or unloads the substrate W into or from the process chambers 400 and 500 through an entrance. The plurality of hands 320 may be provided to transfer the substrates W in different states. For example, some of the plurality of hands 320 may be provided to transfer the substrate W before being loaded into the process chambers 400 and 500, and others may be provided to transfer the process-completed substrate W in the process chambers 400 and 500.

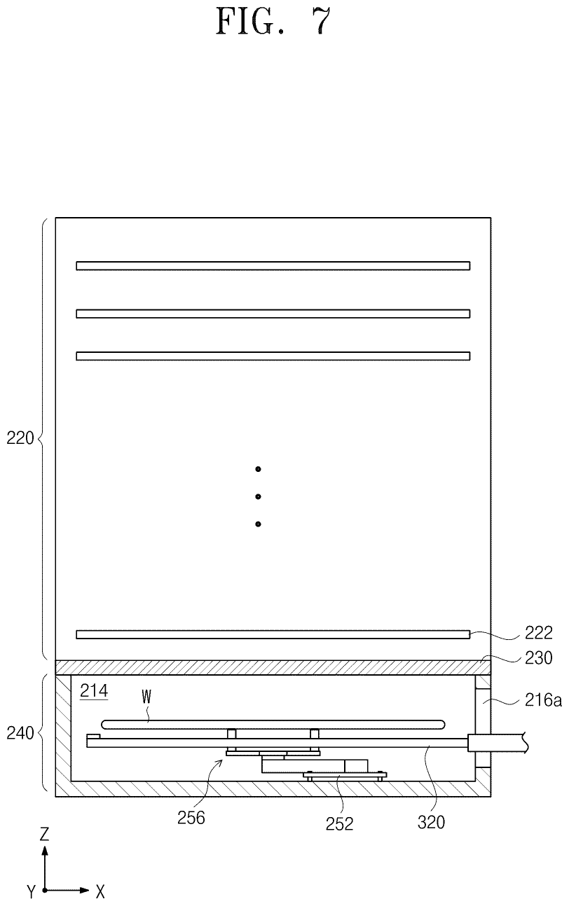

FIG. 7 is a diagram illustrating a state in which a substrate supported by the hand of FIG. 6 is transferred to the weight measuring unit to measure the weight. The hand 320 may advance relative to the base 310 while supporting the bottom surface of the substrate W and load the substrate W into the weight measurement space 214. The hand 320 may descend to the forward position and hand over the substrate W from the hand 320 to the support 256 of the weight measuring unit 250. In other words, as the hand 320 descends, the upper end of the support protrusion 256b of the support 256 may come into contact with the bottom surface of the substrate W, and as the hand 320 continuously descends, the hand 320 and the substrate W are spaced apart from each other by the support protrusions 256b, and thus the weight measuring unit 250 may measure the weight of the substrate W. After the weight measuring unit 250 measures the weight of the substrate W, the hand 320 may ascend again and hand over the substrate W from the support 256 of the weight measuring unit 250.

FIG. 8 is a top plan view of the weight measurement space of FIG. 7. Referring further to FIG. 8, the hand 320 may include a pair of fingers 324 and 326 capable of supporting the bottom surface of the substrate W. The pair of fingers 324 and 326 may be provided in a rod shape extending in one direction to support the bottom surface of the substrate W.

The pair of fingers 324 and 326 and the support protrusions 256b may be configured and disposed so as not to interfere with each other when the hand 320 moves upward and downward in the weight measurement space 214. The hand 320 and the support protrusion 256b may be disposed so that the substrate W is transferred between the hand 320 and the support protrusion 256b as the hand 320 ascends and descends. In other words, the support protrusion 256b may be configured so that the hand 320 and the support protrusion 256b do not collide with each other in a series of process in which the hand 320 descends within the weight measurement space 214 to hand over the substrate W to the support protrusion 256b or the hand 320 ascends to take over the substrate W from the support protrusion 256b.

For example, as illustrated in FIG. 8, a distance L2 between the pair of fingers 324 and 326 is greater than the distance L1 between the two adjacent support protrusions 256b, so that the hand 320 and the support protrusions 256b may be disposed not to overlap when viewed from above.

Referring back to FIG. 1, the process chambers 400 and 500 may process the substrate W. The process chambers 400 and 500 may include a first process chamber 400 and a second process chamber 500. For example, the first process chamber 400 and the second process chamber 500 may be sequentially disposed on opposite sides of the transfer frame 300 in the first direction X. On the contrary, the first process chambers 400 may be disposed on one side of the transfer frame 300 in the first direction X, and the second process chambers 500 may be disposed on the other side of the transfer frame 300 in the first direction X.

The first process chamber 400 and the second process chamber 500 may be provided to sequentially perform a process on one substrate W. The first process chamber 400 may be provided as a liquid treating chamber for liquid-treating a substrate, and the second process chamber 500 may be provided as a drying chamber for removing a liquid remaining on the substrate. For example, a chemical process, a rinsing process, and a substitution process may be performed on the substrate W in the first process chamber 400, and a drying process may be performed on the substrate W in the second process chamber 500. In this case, the substitution process may be performed by an organic solvent, and the drying process may be performed by a supercritical fluid. An isopropyl alcohol (IPA) liquid may be used as the organic solvent, and carbon dioxide (CO2) may be used as the supercritical fluid.

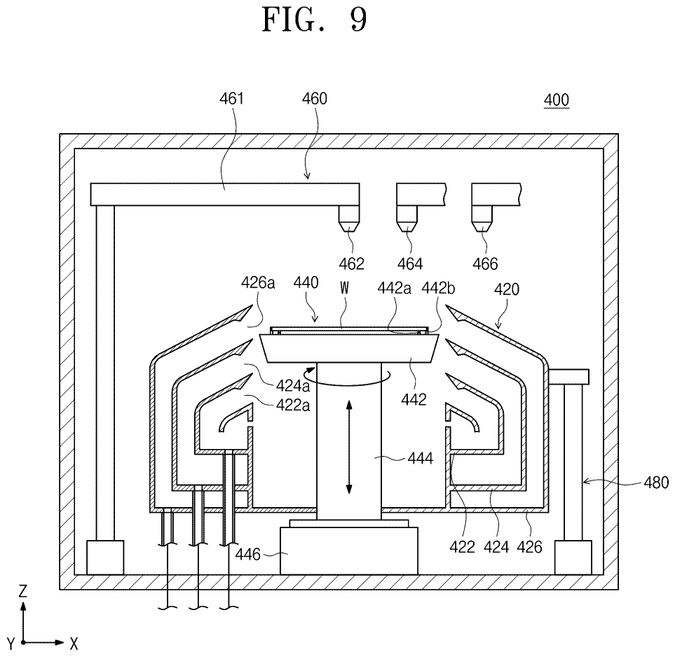

FIG. 9 is a diagram schematically illustrating an exemplary embodiment of the first process chamber of FIG. 1. Referring to FIG. 9, the first process chamber 400 may include a housing 410, a cup 420, a support unit 440, a liquid supply unit 460, and a lifting unit 480.

The housing 410 is provided in a generally rectangular parallelepiped shape. The cup 420, the support unit 440, and the liquid supply unit 460 may be disposed within the housing 410.

The cup 420 has a treatment space with an open top, and the substrate W is liquid-treated in the treatment space. The support unit 440 supports the substrate W in a treatment space. The liquid supply unit 460 supplies the liquid onto the substrate W supported by the support unit 440. The liquid may be provided in a plurality of types, and may be sequentially supplied onto the substrate W. The lifting unit 480 adjusts a relative height between the cup 420 and the support unit 440.

According to an example, the cup 420 may include a plurality of recovery containers 422, 424, and 426. Each of the recovery containers 422, 424, and 426 has a recovery space for recovering the liquid used for the processing of the substrate. Each of the recovery containers 422, 424, and 426 is provided in a ring shape surrounding the support unit 440. As the liquid treating process proceeds, the treatment liquid scattered by the rotation of the substrate W is introduced into the recovery space through the inlets 422a, 424a, and 426a of the recovery containers 422, 424, and 426, respectively. According to the example, the cup 420 includes a first recovery container 422, a second recovery container 424, and a third recovery container 426. The first recovery container 422 is disposed to surround the support unit 440, the second recovery container 424 is disposed to surround the first recovery container 422, and the third recovery container 426 is disposed to surround the second recovery container 424. A second inlet 424a through which the liquid flows into the second recovery container 424 may be located above a first inlet 422a through which the liquid flows into the first recovery container 422, and a third inlet 426a through which the liquid flows into the third recovery container 426 may be located above the second inlet 424a.

The support unit 440 includes a support plate 442 and a drive shaft 444. An upper surface of the support plate 442 may be provided in a generally circular shape, and may have a diameter larger than a diameter of the substrate W. A support pin 442a for supporting a rear surface of the substrate W is provided at the center portion of the support plate 442, and an upper end of the support pin 442a protrudes from the support plate 442 such that the substrate W is spaced apart from the support plate 442 by a predetermined distance. A chuck pin 442b is provided at an edge of the support plate 442. The chuck pin 442b is provided to protrude upward from the support plate 442, and supports a side portion of the substrate W so that the substrate W is not separated from the supporting unit 440 when the substrate W is rotated. The drive shaft 444 is driven by the driver 446, is connected to a center of a bottom surface of the substrate W, and rotates the support plate 442 with respect to its central axis.

According to an example, the liquid supply unit 460 may include a first nozzle 462, a second nozzle 464, and a third nozzle 466. The first nozzle 462 may supply the first liquid onto the substrate W. The first liquid may be a liquid that removes a film or foreign substances remaining on the substrate W. The second nozzle 464 may supply a second liquid onto the substrate W. The second liquid may be a liquid that is well soluble in a third liquid. For example, the second liquid may be a liquid that is more easily soluble in the third liquid than in the first liquid. The second liquid may be a liquid that neutralizes the first liquid supplied onto the substrate W. Also, the second liquid may be a liquid that neutralizes the first liquid and is soluble better in the third liquid compared to the first liquid. According to an example, the second liquid may be pure water (DIW). The third nozzle 466 may supply the third liquid onto the substrate W. The third liquid may be a liquid that is well soluble in a supercritical fluid used in the second process chamber 500. According to an example, the third liquid may be a volatile organic solvent, pure water, or a mixture of pure water and a surfactant. The third liquid may be an organic solvent. The organic solvent may be isopropyl alcohol (IPA). According to an example, the supercritical fluid may be carbon dioxide. The substrate may be unloaded from the first process chamber 400 in a state in which the third liquid is applied and loaded into the second process chamber 500.

The first nozzle 462, the second nozzle 464, and the third nozzle 466 are supported by different arms 461, and these arms 461 may be moved independently. Selectively, the first nozzle 462, the second nozzle 464, and the third nozzle 466 may be mounted on the same arm 461 and simultaneously moved.

The lifting unit 480 moves the cup 420 in the vertical direction. By the vertical movement of the cup 420, a relative height between the cup 420 and the substrate W is changed. Accordingly, the recovery containers 422, 424, and 426 for recovering the treatment liquid are changed according to the type of liquid supplied to the substrate W, and thus the liquids may be separated and recovered. Unlike the description, the cup 420 is fixedly installed, and the lifting unit 480 may move the support unit 440 in the vertical direction.

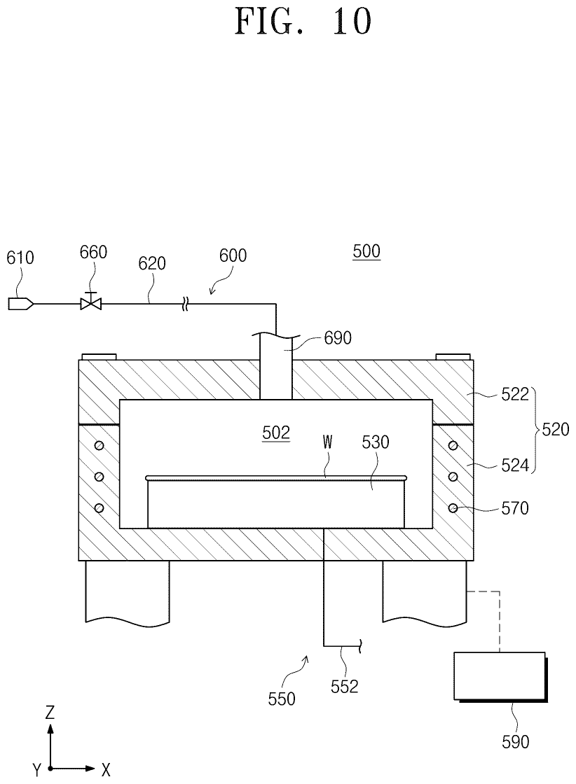

FIG. 10 is a diagram schematically illustrating an exemplary embodiment of the second process chamber of FIG. 1.

According to an example, the second process chamber 500 removes a liquid on the substrate W by using a supercritical fluid. A cleaning device 500 may include a body 520, a substrate support body 530, and a fluid supply unit 600.

The body 520 may provide a treatment space 502 in which a cleaning process is performed. The body 520 may have an upper body 522 and a lower body 524 and the upper body 522 and the lower body 524 may be combined to provide the above-described treatment space 502. The upper body 522 is provided at the upper portion of the lower body 524. The upper body 522 may be fixed in position, and the lower body 524 may be raised and lowered by a driving member 590, such as a cylinder. When the lower body 524 is spaced apart from the upper body 522, the treatment space 502 is opened, and in this case, the substrate W is loaded and unloaded. During the drying process, the lower body 524 is in close contact with the upper body 522 so that the treatment space 502 is sealed from the outside.

The second process chamber 500 may include a heater 570. According to an example, the heater 570 may be located inside a wall of the body 520. The heater 570 may heat the treatment space 502 of the body 520 so that the fluid supplied into the inner space of the body 520 maintains a supercritical state. An atmosphere by the supercritical fluid is formed inside the treatment space 502.

The substrate support body 530 supports the substrate W in the treatment space 502 of the body 520.

The fluid supply unit 600 supplies a cleaning fluid to the treatment space 502 of the body 520. According to an example, the cleaning fluid may be supplied to the treatment space 502 in a supercritical state. In contrast, the cleaning fluid may be supplied to the treatment space 502 in a gaseous state and may be phase-changed to a supercritical state within the treatment space 502.

According to an example, the fluid supply unit 600 includes a fluid supply port 690, a supply line 620, and a valve 660. The fluid supply port 690 directly supplies the supercritical fluid to the upper surface of the substrate W. The fluid supply port 690 is provided by being connected to the upper body 522. The fluid supply unit 600 may further include a lower fluid supply port (not illustrated) connected to the lower body 524. The supercritical fluid injected from the fluid supply port 690 reaches the central region of the substrate W and spreads to the edge region, thereby being uniformly provided to the entire region of the substrate W. The supply line 620 is connected to the fluid supply port 690. The supply line 620 receives the supercritical fluid from an outside separate supercritical fluid storage unit 610, and supplies the supercritical fluid to the fluid supply port 690. For example, the supercritical fluid storage unit 610 may store a supercritical fluid, which may be carbon dioxide or the like, and supply the supercritical fluid to the supply line 620.

The valve 660 is installed in the supply line 620. The valve 660 adjusts the flow rate of the supercritical fluid supplied to the fluid supply port 690. The valve 660 may adjust the flow rate supplied into the treatment space 502 by a controller (not illustrated).

The exhaust member 550 exhausts the supercritical fluid from the second process chamber 500. The exhaust member 550 may be connected to an exhaust line 552 that exhausts the supercritical fluid. In this case, a valve (not illustrated) may be installed in the exhaust member 550 to adjust the flow rate of the supercritical fluid exhausted to the exhaust line 552. The supercritical fluid exhausted through the exhaust line 552 may be released into the air or may be supplied to a supercritical fluid regeneration system (not illustrated). The exhaust member 550 may be coupled to the lower body 524.

Hereinafter, an exemplary embodiment of a method of processing a substrate using the substrate processing apparatus of FIG. 1 will be described. The substrate processing method described below may be performed by the substrate processing apparatus 1 including the index module 10, the buffer unit 200, the first process chamber 400, the second process chamber 500, and the transfer unit 304. Further, the controller 30 may perform the substrate processing method described below by controlling the components of the substrate processing apparatus 1.

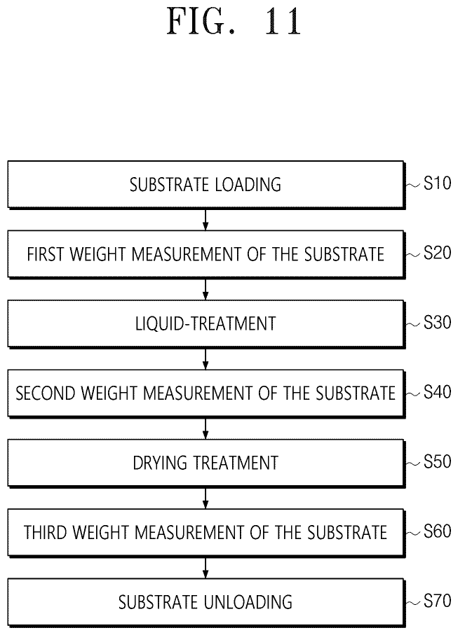

FIG. 11 is a flowchart illustrating a method of processing a substrate using the above-described substrate processing apparatus.

Referring to FIG. 11, the substrate processing method of the present invention includes a substrate loading operation S10, a first weight measuring operation S20, a liquid treating operation S30, a second weight measuring operation S40, a dry treating operation S50, a third weight measuring operation S60, and a substrate unloading operation S70. The above-described substrate loading operation S10 to substrate unloading operation S70 may be sequentially performed.

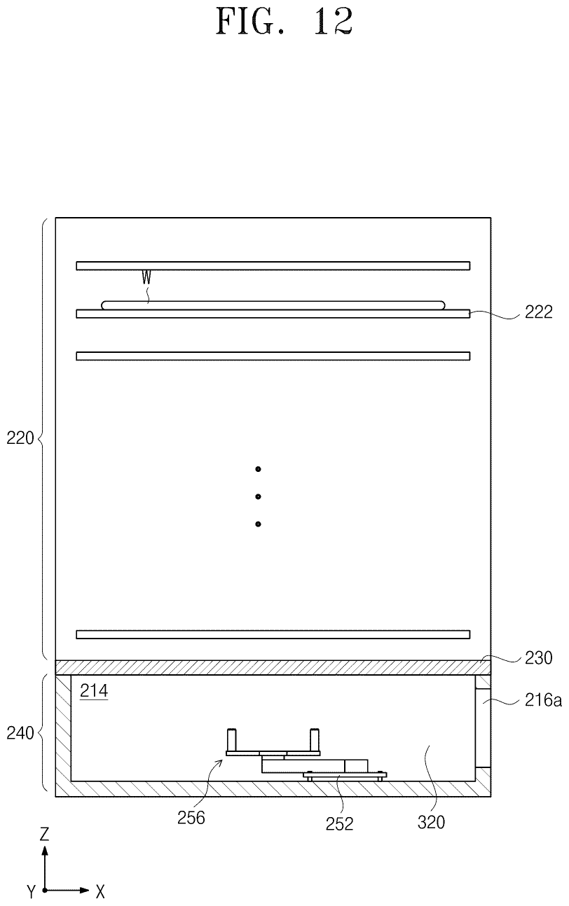

FIG. 12 is a diagram illustrating a shape of the buffer unit in the substrate loading operation of FIG. 11. Referring to FIG. 12, the substrate W is loaded into the buffer part 220 of the buffer unit 200 in the substrate loading operation S10. The index robot 144 may transfer the substrate W from the load port 120 of the index module 10 to the buffer unit 200. The substrate W loaded into the buffer part 220 may be supported by the slot member 222.

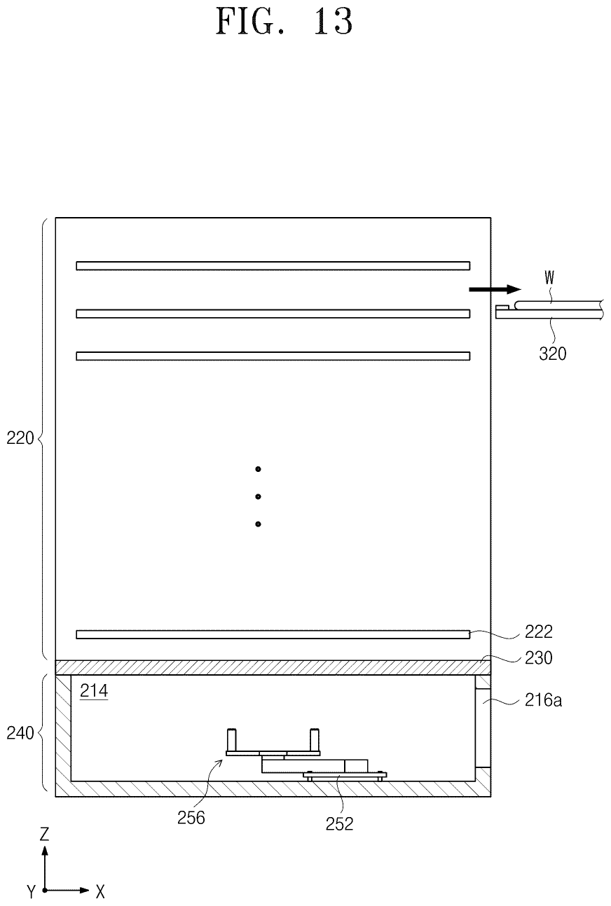

The first weight measuring operation S20 is performed on the substrate W loaded into the buffer part 220. In a first weight measuring operation S20, the weight of the substrate W is measured before the substrate W is liquid-treated in the first process chamber 400. FIGS. 13 to 16 are diagrams illustrating the buffer unit and the hand in the first weight measuring operation of FIG. 10. Hereinafter, the first weight measuring operation S20 will be described in detail with reference to FIGS. 13 to 16.

As illustrated in FIG. 13, the hand 320 of the transfer unit 304 may move to the forward position and take over the substrate W from the buffer part 220.

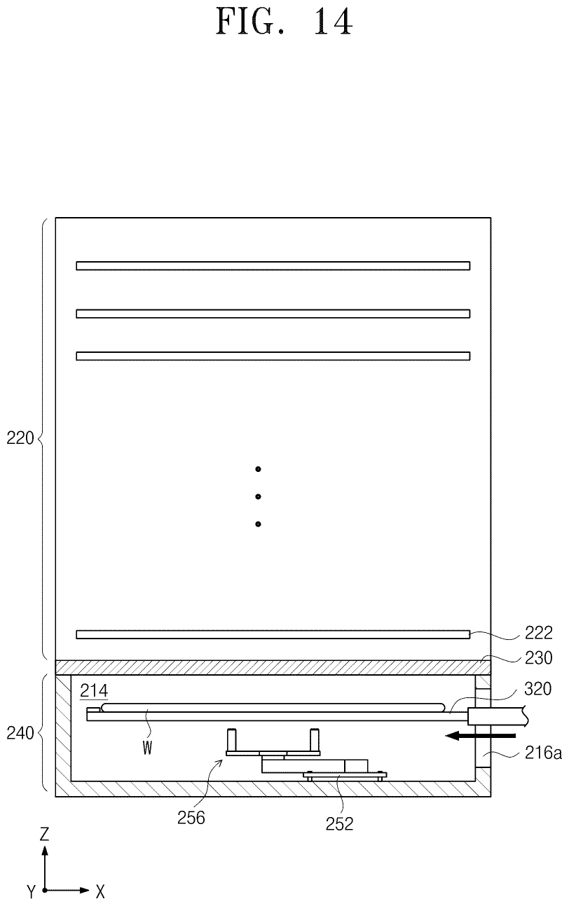

As illustrated in FIG. 14, the transfer unit 304 may lower the hand 320 and load the substrate W into the weight measurement space 214 through the opening 216a formed in the rear surface of the weight measuring part 240. In this case, the hand 320 is placed in the forward position with respect to the base 310.

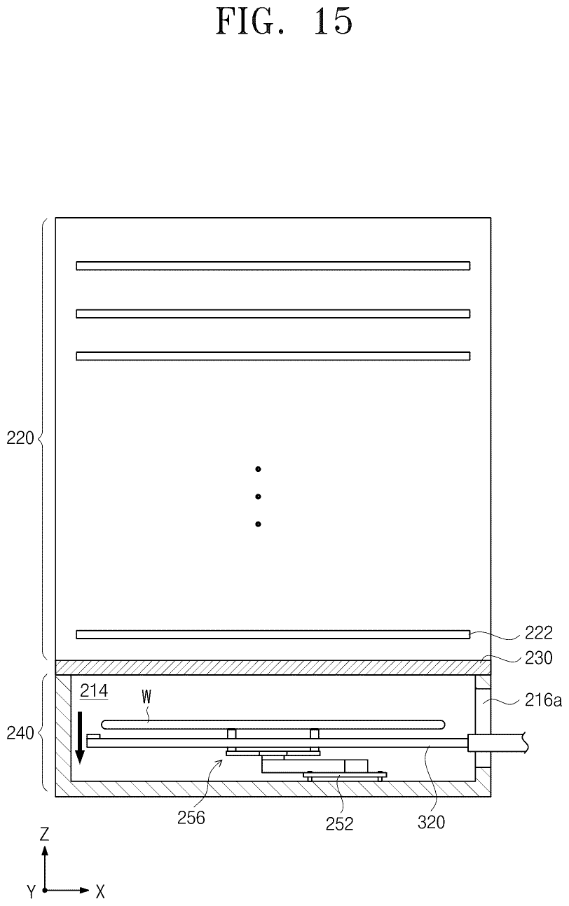

As illustrated in FIG. 15, the hand 320 descends from the support 256 of the weight measuring unit 250, and the substrate W is handed over from the hand 320 to the support 256 and supported by the support protrusion 256b. When the hand 320 continuously descends and is spaced apart from the substrate W, the weight measuring sensor 254 measures the weight of the substrate W. While the weight of the substrate W is measured, the hand 320 may wait while being positioned below the substrate W. In other words, while the weight of the substrate W is measured, the hand 320 may be in the forward position with respect to the base 310.

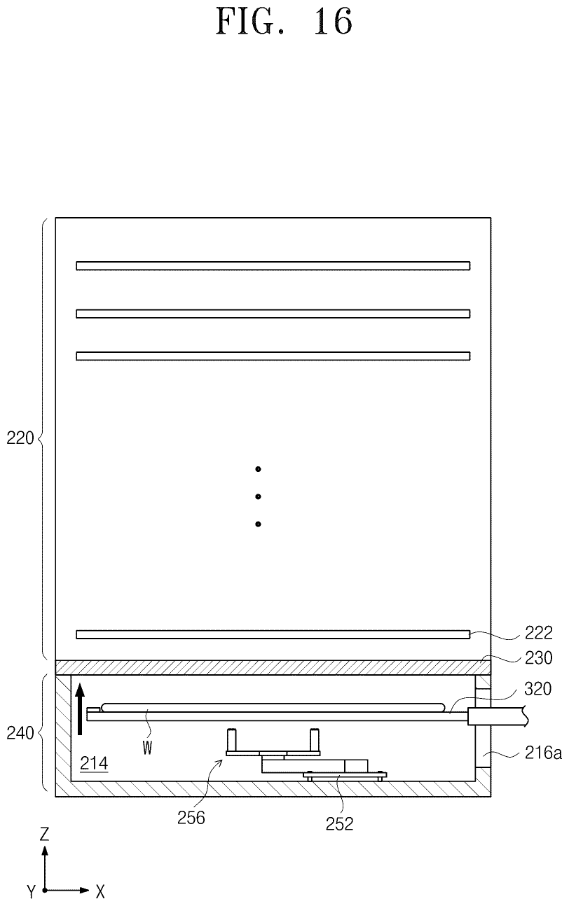

As illustrated in FIG. 16, when the weight measurement for the substrate W is completed, the hand 320 rises and takes over the substrate W from the support 256, unloads the substrate W out of the weight measurement space 214, and the first weight measuring operation S20 is finished.

After the first weight measuring operation S20, the liquid treating operation S30 is performed. In the liquid treating operation S30, the transfer unit 304 may transfer the substrate W to the first process chamber 400. The first process chamber 400 may perform the liquid treatment on the transferred substrate W. The transfer unit 304 may unload the substrate W, on which the liquid treatment has been completed, from the first process chamber 400. A liquid may be applied on the substrate W, which has been unloaded from the first process chamber 400 after the liquid treatment has been completed. For example, a third liquid may remain on the substrate W, which has been unloaded from the first process chamber 400 after the liquid treatment has been completed.

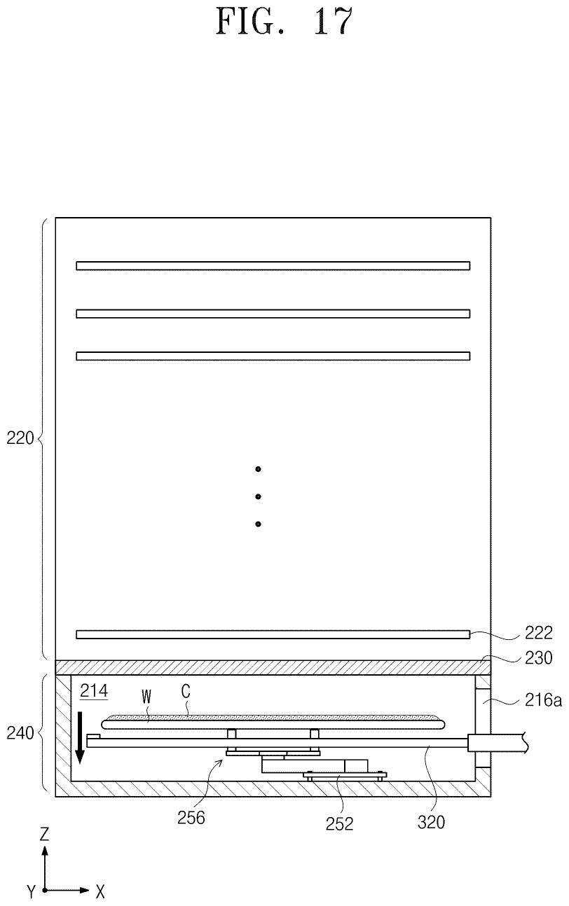

After the liquid treating operation S30, the second weight measuring operation S40 is performed. In the second weight measuring operation S40, the weight of the substrate W after the substrate W is liquid-treated in the first process chamber 400 is measured. In the second weight measuring operation S40, the weight of the substrate W in the state in which the liquid is applied and the liquid film C is formed, which is unloaded from the first process chamber 400 after the liquid treatment. The weight measurement of the substrate W in the second weight measuring operation S40 is performed in the same manner as in the first weight measuring operation S20 described with reference to FIGS. 13 to 16. FIG. 17 is a diagram illustrating a state in which the weight of the substrate W is measured in the second weight measuring operation.

Referring to FIG. 17, compared to FIG. 15 in which the weight of the substrate W is measured in the first weight measuring operation S20, there is a difference in that a liquid film C is formed on the substrate W.

The controller 30 may derive the weight of the liquid applied on the substrate W by calculating the difference between the weight of the substrate W measured by the weight measuring sensor 254 in the second weight measuring operation S40 and the weight of the substrate W measured by the weight measuring sensor 254 in the first weight measuring operation S20.

After the second weight measuring operation S40, the drying treatment operation S50 is performed. In the drying treatment operation S50, the transfer unit 304 may transfer the substrate W to the second process chamber 500. The second process chamber 500 may dry-treat the transferred substrate W. The transfer unit 304 may unload the substrate W, on which the drying treatment has been complete, from the second process chamber 500.

After the drying process S50, the third weight measuring operation S60 is performed. In the third weight measuring operation S60, the weight of the substrate W is measured after the substrate W is dried in the second process chamber 500. In the third weight measuring operation S60, the weight of the substrate W, which has been unloaded from the second process chamber 500 after the drying treatment, in a state in which the liquid film C is removed, may be measured.

The weight measurement for the substrate W in the third weight measuring operation S60 is performed in the same manner as in the first weight measuring operation S20 described above with reference to FIGS. 13 to 16.

The controller 30 may determine whether the liquid applied on the substrate W is entirely dried from the weight data of the substrate W measured by the weight measuring sensor 254 in the first weight measuring operation S20, the second weight measuring operation S40, and the third weight measuring operation S60.

When the third weight measuring operation S60 is terminated, the substrate unloading operation S70 is performed.

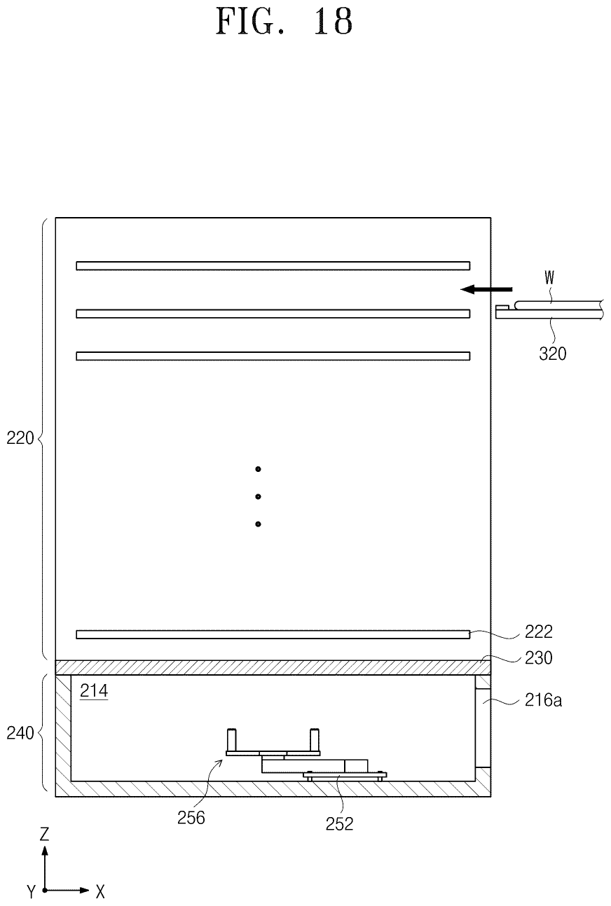

FIG. 18 is a diagram illustrating a state of the buffer unit and the hand when a substrate unloading operation of FIG. 10 is performed. Referring to FIG. 18, the hand 320 of the transfer unit 304 may be moved to the forward position to transfer the substrate W to the buffer part 220.

Before the above-described substrate weight measuring steps S20, S40, and S60 are performed, the weight measuring sensor 254 may perform an initialization process for the measured weight value. By initializing the weight value measured before the weight measurement is performed on the substrate W to adjust the zero point, it is possible to minimize an error that may occur due to long-term non-use or an error due to residual weight.

According to the above-described exemplary embodiment, the weight of the substrate W is measured in the substrate processing apparatus 1. For this reason, it is possible to measure the weight of the substrate W in the actual process atmosphere of processing the substrate W, and to detect an appropriate amount of the residual liquid on the substrate W during the process. For this reason, process defects may be prevented due to insufficient and excessive liquid.

According to the above-described exemplary embodiment, the present invention may automate the weight measurement process of the substrate W and increase the substrate processing efficiency by arranging the weight measuring unit 250 in the weight measuring part 240 under the buffer unit 200 and configuring the transfer unit 304 to enter and exit.

In addition, according to the above-described exemplary embodiment, by configuring the weight measuring unit 250 under the buffer unit 200 and providing a cover 230 above the weight measuring unit 250, it is possible to block the descending airflow introduced into the buffer unit 200 and the weight measuring unit 250 to minimize errors in the weight measurement of the substrate W due to the descending airflow.

In addition, according to the above-described exemplary embodiment, by forming the hole 232 in the cover 230 to discharge the atmosphere in the weight measurement space 214, the substrate W to which the liquid film C is applied may be loaded into the weight measurement space 214, and steam and the like that may be generated by volatilization of the liquid film C and the like may be discharged to the outside of the weight measurement space 214, and reverse contamination of the substrate W may be prevented.

Although not described in the above exemplary embodiment, a seating sensor or the like for checking whether the substrate W is seated in the buffer space 212 may be installed in the upper portion of the buffer unit 200. By configuring the weight measuring unit 250 in the lower portion of the buffer unit 200, the arrangement structure of the seating sensor or the detection path of the sensor may be optimized.

Although not described in the above-described exemplary embodiment, when the weight measurement value of the substrate W measured by the weight measuring unit 250 is out of a preset range or the weight of the liquid on the substrate W measured by the weight measuring unit 250 is out of a preset range, the substrate processing device 1 may be controlled to take measures, such as notification.

In the above exemplary embodiment, although it has been illustrated and described that the four support protrusions 256b of the weight measuring unit 250 are provided, the present invention is not limited thereto. The number of the plurality of support protrusions 256b and the arrangement relationship between the support protrusions 256b may be freely modified. The support protrusion 256b may be disposed at a position at which warpage due to its own weight of the substrate W may be minimized when supporting the bottom surface of the substrate W, and may be disposed so as not to interfere with the hand 320 in a process in which the hand W ascends in the weight measurement space 214 and exchanges the substrate W with the support protrusion 256b.

In the above-described exemplary embodiment, the distance L2 between the pair of fingers 324 and 326 of the hand 320 is provided to be greater than the distance L1 between the two adjacent support protrusions 256b. However, when viewed from above, it is sufficient when the hand 320 and the support protrusions 256b are disposed not to overlap, and the distance L2 between the pair of fingers 324 and 326 of the hand 320 may be provided to be less than the distance L1 between the two adjacent support protrusions 256b.

In the above exemplary embodiment, it is illustrated and described that the front surface of the weight measurement space 214 of the buffer unit 200 is closed and the opening 216a is formed at the rear surface thereof, but the present invention is not limited thereto. An opening may be formed not only at the rear surface of the weight measurement space 214 but also at the front surface, and the index hand 146 of the index robot 144 may be configured to enter and exit the weight measurement space 214 through the opening formed at the front surface.

In the above exemplary embodiment, the present invention has been described based on the case where the weight measuring sensor 254 includes the load cell 254a for measuring strain through a strain gauge, and the weight measuring sensor 254 is provided in the cantilever shape as an example. Alternatively, unlike this, the weight measuring sensor 254 may be provided as other known means capable of measuring weight, and the arrangement structure and shape thereof may also be freely changed.

The foregoing detailed description illustrates the present invention. Further, the above content shows and describes the exemplary embodiment of the present invention, and the present invention may be used in various other combinations, modifications, and environments. That is, the foregoing content may be modified or corrected within the scope of the concept of the invention disclosed in the present specification, the scope equivalent to that of the invention, and/or the scope of the skill or knowledge in the art. The foregoing exemplary embodiment describes the best state for implementing the technical spirit of the present invention, and various changes required in specific application fields and uses of the present invention are possible. Accordingly, the detailed description of the invention above is not intended to limit the invention to the disclosed exemplary embodiment. Further, the accompanying claims should be construed to include other exemplary embodiments as well.

What is claimed is:

1. An apparatus for processing a substrate, the apparatus comprising:
an index module including a load port and an index robot; and
a treating module including a buffer unit, a liquid treating chamber for liquid-treating a substrate, a drying chamber for removing the liquid remaining on the substrate, and a transfer unit for transferring the substrate between the buffer unit, the liquid treating chamber, and the drying chamber,
wherein the buffer unit includes:
a frame;
a buffer disposed in an upper space of an inner space of the frame and temporarily storing the substrate transferred between the index module and the treating module; and
a weight measuring unit disposed in a lower space of the inner space of the frame and measuring the weight of the substrate.

2. The apparatus of claim 1, wherein the weight measuring unit includes:
a support on which the substrate is placed;
a weight measuring sensor for measuring the weight of the substrate placed on the support; and
a measuring device base for supporting the weight measuring sensor.

3. The apparatus of claim 2, wherein the weight measuring sensor includes a load cell.

4. The apparatus of claim 2, wherein the weight measuring sensor has a cantilever shape, and has one end supported by the measuring device base, and
the support is installed on the other end of the weight measuring sensor.

5. The apparatus of claim 2, wherein the weight measuring unit further includes a level-adjusting member for adjusting horizontality of the support.

6. The apparatus of claim 2, wherein the support includes:
a bottom plate; and
a plurality of support protrusions protruding upward from the bottom plate and being in contact with a bottom surface of the substrate, and
the plurality of support protrusions are disposed to support the substrate at points spaced apart from each other.

7. The apparatus of claim 6, wherein a distance between two support protrusions adjacent to each other among the plurality of support protrusions is smaller than a radius of the substrate.

8. The apparatus of claim 6, wherein the transfer unit includes:
a base; and
a hand configured to advance and retract relative to the base and support the substrate, and
the hand and the support protrusions are disposed so that the substrate is handed over between the hand and the plurality of support protrusions as the hand is raised and lowered.

9. The apparatus of claim 1, further comprising:
an airflow supply unit for providing descending airflow to a region where the buffer unit is provided,
wherein the buffer unit further includes a cover for dividing the inner space of the frame into the upper space and the lower space.

10. The apparatus of claim 9, wherein a vertically penetrating hole is formed in the cover.

11. The apparatus of claim 1, wherein the upper space has an open front face facing the index robot and an open rear face facing the transfer unit, and
in the lower space, the front face and the rear face are closed, and an opening through which the substrate enters and exits is formed on the rear face.

12. The apparatus of claim 11, further comprising:
a shutter configured to open and close the opening.

13. An apparatus for processing a substrate, the apparatus comprising:
an index module including a load port and an index robot; and
a treating module including a buffer unit, a process chamber for processing a substrate, and a transfer unit for transferring the substrate between the buffer unit and the process chamber,
wherein the buffer unit includes:
a frame;
a buffer disposed in an upper space of an inner space of the frame and temporarily storing the substrate transferred between the index module and the treating module;
a weight measuring unit disposed in a lower space of the inner space of the frame and measuring a weight of the substrate; and
a cover for dividing the inner space of the frame into the upper space and the lower space.

14. The apparatus of claim 13, wherein the weight measuring unit includes:
a support on which the substrate is placed;
a weight measuring sensor for measuring the weight of the substrate placed on the support; and
a measuring device base for supporting the weight measuring sensor,
the support includes:
a bottom plate; and
a plurality of support protrusions protruding upward from the bottom plate and being in contact with a bottom surface of the substrate,
the plurality of support protrusions is disposed to support the substrate at points spaced apart from each other, and
a distance between two support protrusions adjacent to each other among the plurality of support protrusions is smaller than a radius of the substrate.

15. The apparatus of claim 14, wherein a vertically penetrating hole is formed in the cover.

16. The apparatus of claim 14, wherein the weight measuring sensor has a cantilever shape, and has one end supported by the measuring device base, and
the support is installed on the other end of the weight measuring sensor.

17. The apparatus of claim 13, wherein the upper space has an open front face facing the index robot and an open rear face facing the transfer unit, and
in the lower space, the front face and the rear face are closed, and an opening through which the substrate enters and exits is formed on the rear face.

18. An apparatus for processing a substrate, the apparatus comprising:
an index module including a load port and an index robot; and
a treating module including a transfer frame in which a buffer unit, a liquid treating chamber for liquid-treating a substrate, a drying chamber for removing the liquid remaining on the substrate by supplying a supercritical fluid to the substrate, and a transfer unit for transferring the substrate between the buffer unit, the liquid treating chamber, and the drying chamber,
wherein the buffer unit includes:
a frame;
a buffer disposed in an upper space of an inner space of the frame and temporarily storing the substrate transferred between the index module and the treating module;
a weight measuring unit disposed in a lower space of the inner space of the frame and measuring a weight of the substrate; and
a cover for dividing the inner space of the frame into the upper space and the lower space,
the upper space has an open front face facing the index robot and an open rear face facing the transfer unit,
in the lower space, the front face and the rear face are all closed, and an opening through which the substrate enters and exits is formed on the rear face,
a vertically penetrating hole may be formed in the cover, and
the weight measuring unit includes:
a support on which the substrate is placed;
a weight measuring sensor for measuring the weight of the substrate placed on the support; and
a measuring device base for supporting the weight measuring sensor.

19. The apparatus of claim 18, wherein the weight measuring unit further includes a level-adjusting member for adjusting horizontality of the support,
the support includes:
a bottom plate; and
a plurality of support protrusions protruding upward from the bottom plate and being in contact with a bottom surface of the substrate,
the plurality of support protrusions is disposed to support the substrate at points spaced apart from each other, and
a distance between two support protrusions adjacent to each other among the plurality of support protrusions is smaller than a radius of the substrate.

20. The apparatus of claim 18, wherein the weight measuring sensor has a cantilever shape, and has one end supported by the measuring device base, and
the support is installed on the other end of the weight measuring sensor.
